(19) United States
(12) Patent Application Publication
(10) Pub. No.: US 2025/0350267 A1
(43) Pub. Date: Nov. 13, 2025

(54) INTEGRATOR-BASED TRIANGULAR WAVE GENERATOR

(71) Applicant: Intel Corporation, Santa Clara, CA (US)

(72) Inventors: Huanhuan Zhang, Ashland, MA (US); Syed Askari, Folsom, CA (US); Yura Kocharyan, Fremont, CA (US); Christopher Schaef, San Diego, CA (US); Keng Chen, Acton, MA (US); Maximilian Geppert, Beaverton, OR (US); Kelly Livingston, Beaverton, OR (US)

(21) Appl. No.: 18/662,891

(22) Filed: May 13, 2024

(51) Int. Cl. H03K 4/06; G06F 1/26; H02M 1/14; H02M 1/44; H02M 3/07

(52) U.S. Cl. CPC H03K 4/06; G06F 1/26; H02M 3/07; H02M 1/14; H02M 1/44

(57) ABSTRACT

Embodiments herein relate to a current source for a waveform generator in a voltage regulator (VR). In one approach, the current source is provided as a switched-capacitor frequency-to-current converter. The current source includes a switching circuit, a continuous-time integrator, and an adaptive multi-stage filter. The switching circuit receives a clock signal which is used to control switches to provide a time-varying voltage and current. The voltage and current are low-pass filtered at the continuous-time integrator before being filtered at the adaptive multi-stage filter. An output current of the adaptive multi-stage filter is then provided as an input current to a waveform generator such as to provide a pulse-width modulation signal for driving a powertrain of the VR. In another aspect, the current source includes a switching circuit and a discrete or digital integrator.

### BACKGROUND

Computing devices often rely on voltage regulators (VRs) to obtain power. A VR is an electrical circuit which accepts a direct current (DC) input and generates a DC output of a different voltage, usually achieved by high frequency switching of inductive and/or capacitive elements. For example, a VR can convert the main supply voltage of a computing device, such as 12-48 V, down to lower voltages, such as about 1 V. The lower voltages can be used by various components in the computing device, such as a Universal Serial Bus (USB) interface, memory such as dynamic random access memory (DRAM) and processing resources such as a central processing unit (CPU). However, it is challenging to supply power efficiently.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 depicts an example of a voltage regulator (VR) circuit 100 including a current source 110 and a waveform generator 120, in accordance with various embodiments.

FIG. 2 depicts a delay-locked loop (DLL) circuit 200 in an example implementation of the current source 110 of FIG. 1, in accordance with various embodiments.

FIG. 3 depicts an example implementation of the waveform generator 120 of FIG. 1, in accordance with various embodiments.

FIG. 4 depicts example waveforms for use in the circuits of FIGS. 2 and 3, in accordance with various embodiments.

FIG. 5 is an example table of variations in a calibration code, cal_code, versus input clock frequency for the circuit of FIG. 3, in accordance with various embodiments.

FIG. 6A depicts a continuous-time integrator-based circuit 600 including a continuous-time integrator 610, an adaptive multi-stage filter 630 and a switching circuit 620 having two-phases, in an example implementation of the current source 110 of FIG. 1, in accordance with various embodiments.

FIG. 6B depicts an example implementation of the circuit 660 of FIG. 6A, in accordance with various embodiments.

FIG. 6C depicts an example metal finger capacitor 680, such as for capacitor 326 in FIG. 3, the capacitors 623 and 624 in FIG. 6A, the capacitors 711, 721, 731 and 741 in FIG. 7, the capacitors 813 and 823 in FIG. 8, and the capacitor 914 in FIG. 9, in accordance with various embodiments.

FIG. 7 depicts an example four-phase switching circuit 700 as an alternative to the switching circuit 620 of FIG. 6A, in accordance with various embodiments.

FIG. 8 depicts an example switching circuit 800 with switch size modulation as an alternative to the switching circuit 620 of FIG. 6A, in accordance with various embodiments.

FIG. 9 depicts a discrete-time integrator-based circuit 900 in an example implementation of the current source 110 of FIG. 1, in accordance with various embodiments.

FIG. 10A depicts an example plot of Vswout versus time consistent with the circuit of FIG. 6A, in accordance with various embodiments.

FIG. 10B depicts an example plot of Vswout_filt versus time consistent with the circuit of FIG. 6A and the plot of FIG. 10A, in accordance with various embodiments.

FIG. 11 depicts an example plot of Ibias versus switching frequency (Fsw) consistent with the circuits of FIGS. 6A and 9, in accordance with various embodiments.

FIG. 12 illustrates an example of components that may be present in a computing system 1250 for implementing the techniques (e.g., operations, processes, methods, and methodologies) described herein.

### DETAILED DESCRIPTION

As mentioned at the outset, various challenges are encountered in efficiently supplying power in a computing device using a voltage regulator (VR).

In some cases, a VR is integrated into a single chip or package to provide power to electronic components of the chip or package. The VR is referred to as a fully integrated VR (FIVR) in this case. In other cases, the VR is separate from the powered components of a chip or package.

A FIVR can be used to provide power to different load domains such as core, memory, and input-output circuits. Since the load range is different for each domain, a FIVR can operate at different switching frequencies to improve efficiency. For example, in modern central processing unit (CPU) designs, the switching frequency specification can range from 20 MHz to 200 MHz. However, operating a FIVR or other VR at a range of frequencies presents a number of challenges. For example, there can be a non-linear relationship between the output voltage of the VR and the switching frequency. This non-linearity can arise from the use of a waveform generator in the FIVR control loop. The waveform generator is challenged to work with a large (e.g., >10×) frequency range while achieving low trim cost, low power and high accuracy. The waveform generator receives an input current from a current source. The input current is used to generate a triangle waveform, and the triangle waveform is used to generate a pulse-width modulation (PWM) signal to drive the high-side and low-side transistors of a powertrain of the VR.

However, there is an inherent mismatch between the device capacitances of the current source and the waveform generator which results in a significant systemic offset. In particular, the current from the current source is not entirely linear with respect to frequency and has a large random offset. The systematic and random offset coming from the current source in addition to the random offset from a current digital-to-analog converter (DAC) can result in saturation of a finite state machine (FSM) used for calibration in the waveform generator and further result in yield loss. Moreover, these inaccuracies will be even greater if the range of clock frequencies increases.

The solutions provided herein address the above and other issues. In one aspect, the current source for a waveform generator in a VR is provided as a switched-capacitor frequency-to-current converter. The current source includes a switching circuit, a continuous-time integrator, and an adaptive multi-stage filter. The switching circuit receives a clock signal which is used to control switches to provide a time-varying voltage and current. The switching circuit includes switches and switched capacitors. The voltage and current are low-pass filtered at the continuous-time integrator before being filtered at the adaptive multi-stage filter. An output current of the adaptive multi-stage filter is then provided as an input current to the waveform generator.

In one aspect, the switching circuit has two sets of switches which are switched by different phases of the clock signal, e.g., 0 and 180 degrees, to reduce ripple. In another aspect, the switching circuit has four sets of switches which are switched by different phases of the clock signal, e.g., 0, 90, 180 and 280 degrees, to further reduce ripple. Additional sets of switches could be used as well. In another aspect, the switching circuit includes a switch size modulation feature in which one switch is selected from a set of different sized switches based on a calibration code from a FSM.

In another aspect, the current source includes a sample-and-hold circuit and a discrete-time integrator. An input path with a respective capacitor is coupled to an input of the sample-and-hold circuit. A voltage held on the respective capacitor is passed to the discrete-time integrator via the switching circuit. An output of the discrete-time integrator modulates a transistor in a first output path which mirrors the current in the input path. A second output path mirrors the current in the first output path to provide an input current for the waveform generator.

The capacitors in the current source and the waveform generator can be of the same type and/or replicas of one another so that they have corresponding process, voltage and temperature (PVT) variations. The similarities of the capacitors helps reduce non-linear behavior and improve accuracy.

The solutions provide a number of advantages including reduced variations in the output voltage of the VR under a wide range of clock frequencies and under large PVT variations. Thus, the variation in trim code is small and within the designed range which guarantees a good yield. Additionally, the current provided by the current source to the waveform generator is a clean current because the switching noise is filtered by the continuous-time integrator and the adaptive multi-stage filter, or by the discrete-time integrator.

These and other features will be further apparent in view of the following discussion.

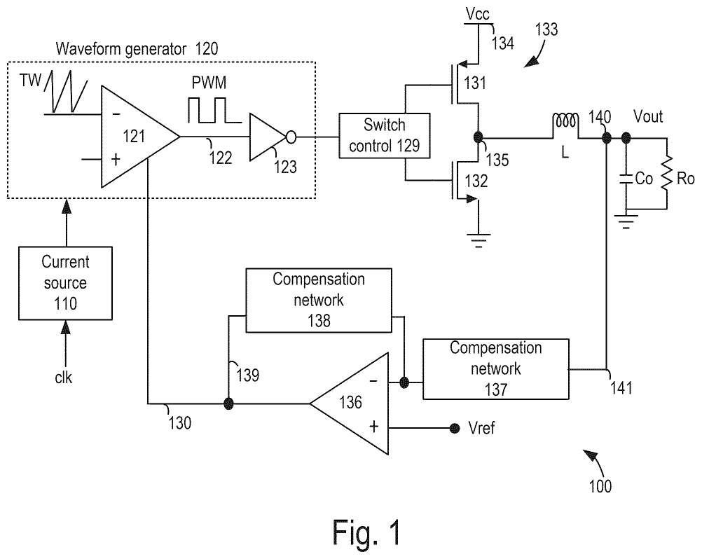

FIG. 1 depicts an example of a voltage regulator (VR) circuit 100 including a current source 110 and a waveform generator 120, in accordance with various embodiments. The current source is responsive to a clock signal clk to output a current to a waveform generator 120. The waveform generator uses the current to generate a triangle waveform (TW) for input to the inverting input of a comparator 121. A voltage is provided at the non-inverting input of the comparator from the output 130 of an amplifier 136. The amplifier receives an output from a first compensation network 137 at its inverting input and a reference voltage, Vref, at its non-inverting input. A second compensation network 138 is provided in a feedforward path 139.

The comparator outputs a PWM signal on a node 122 for input to an inverter 123. The PWM signal has the same frequency as the clock signal. In particular, when the voltage of the TW signal is less than the voltage at the output 130, the PWM signal at the node 122 is high, and when the voltage of the TW signal is greater than the voltage at the output 130, the PWM signal at the node 122 is low. The output of the inverter 123, an inverse of the PWM signal at the node 122, is provided to a switch control circuit 129 which provides charge and discharge switch control signals to drive a high-side transistor 131 and a low-side transistor 132, respectively, of a powertrain 133. In the powertrain, the source of the high-side transistor 131 is biased by a supply voltage Vcc at a node 134, an output node 135 is between the high-side and low-side transistors, and the source of the low-side transistor 132 is coupled to ground.

The VR in this example is a direct current (DC)-to-DC converter that reduces an input voltage from a higher level to a lower level to provide an output voltage and current to a load. A buck VR switches the input voltage on and off at a high frequency, typically by applying PWM signals to the high-side and low-side transistors which are arranged in series in the powertrain. When the high-side transistor is on and the low-side transistor is off, energy is stored in an inductor L, and when the high-side transistor is off and the low-side transistor is on, the inductor releases energy.

The inductor is coupled to an output node 140 at Vout, which in turn is coupled to an output capacitance Co and an output resistance Ro, which represents the load. The load can be a processor or any other component in a computing device. The output node 140 provides Vout on a path 141 to an input of the compensation network 137.

In a VR circuit, a compensation network is a set of components (typically resistors, capacitors, and sometimes inductors) that are added to stabilize the feedback loop and ensure proper performance of the regulator across different operating conditions. Two main types of compensation networks used in voltage regulators are proportional (e.g., including a resistor and a capacitor connected in parallel) and proportional-integral (e.g., including a resistor, a capacitor, and sometimes an additional resistor or inductor).

The waveform generator 120 can also generate clk_delay, a delayed version of clk.

The circuits discussed below provide example implementations regarding the current source 110 and the waveform generator 120.

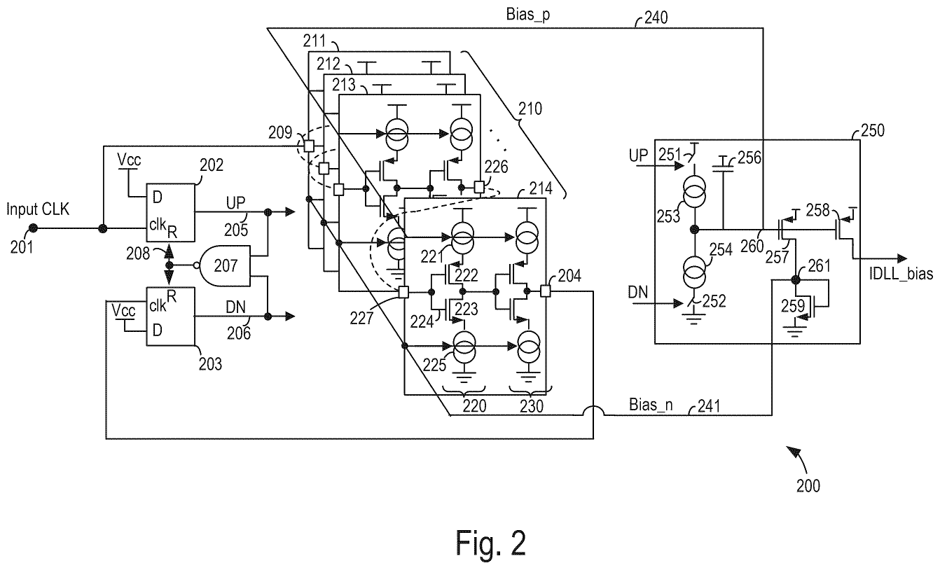

FIG. 2 depicts a delay-locked loop (DLL) circuit 200 in an example implementation of the current source 110 of FIG. 1, in accordance with various embodiments. Generally, a bias current, IDLL_bias, can be generated using a DLL. A DLL has a feedback loop which uses CLK as a reference clock. The clock is shifted by increments up to 360 degrees to generate corresponding clocks with different delays relative to the reference clock. The shift depends on a voltage that the feedback loop generates, where that voltage can also be used to generate the current IDLL_bias that depends the frequency. Ideally, Idll_bias is linearly dependent on the frequency of the input clock signal.

The circuit has an input 201 which receives the input clock (CLK). A first D-type flip-flop 202 receives CLK at its clock (clk) input, Vcc at its data (D) input and a reset signal at its reset (R) input, to provide an output signal UP on a path 205. A second D-type flip-flop 203 receives a signal at a node 204 at its clock (clk) input, Vcc at its data (D) input and the reset signal at its reset (R) input, to provide an output signal DN on a path 206. The signals UP and DN are provided as inputs to a NAND gate 207, which, in response, outputs the reset signal on a path 208.

The DLL includes a delay chain 210 of circuits including individual circuits 211, 212, 213, . . . , 214, which shift the input clock by an increment. Each circuit includes first and second current paths, where each path includes, in series, a current source coupled to a power supply, a p-type and an n-type transistor with their gates connected, and a current sink coupled to ground. For example, the circuit 214 includes a first current path 220 and a second current path 230. The first current path includes a current source 221, a p-type transistor 222 and an n-type transistor 223 having their gates coupled by a path 224, and a current sink 225. Each circuit includes an input node and an output node, where the output node of one circuit is coupled to the input node of the next circuit until the last circuit 214 is reached, which has the final output node 204. The voltage at the node 204 is fed back to the clk input of the flip-flop 203. For example, the output node 226 of the circuit 213 is coupled to the input node 227 of the circuit 214. The input node 209 receives the input CLK.

A bias voltage for the p-type transistors, Bias_p, is provided on a path 240 and a bias voltage for the n-type transistors, Bias_n, is provided on a path 241. The bias voltages are provided by a charge pump 250 at nodes 260 and 261. The charge pump is part of the DLL loop. It uses the UP and DN values to control switches 251 and 252, respectively, generating a bias voltage to propagate to the delay line. The bias voltage also generates the Idll_bias current.

The charge pump 250 receives the signals UP and DN from the flip-flops 202 and 203, respectively, at switches 251 and 252, respectively. The charge pump 250 includes a current path having a power supply node, the switch 251, a current source 253, a current sink 254, the switch 252, and an output node 260 coupled to a capacitor 256. The output node 260 is coupled to the gated of a p-type transistors 257 and 258. The p-type transistor 257 coupled in series with a diode-connected n-type transistor 259 which is coupled to ground. The output of the charge pump 250 is a current IDLL_bias which is input to a waveform generator.

The transistors may be metal-oxide-semiconductor field-effect transistors (MOSFETs), for example.

As mentioned, a disadvantage of a DLL-based current source is that there is an inherent mismatch between device capacitances of the current source and the waveform generator which results in a significant systemic offset, and the current from the current source is not entirely linear with respect to frequency and has a large random offset.

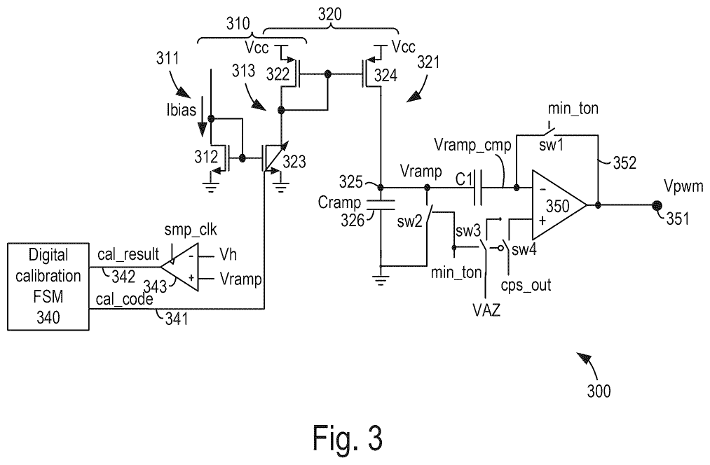

FIG. 3 depicts an example implementation of the waveform generator 120 of FIG. 1, in accordance with various embodiments. The waveform receives a bias current, Ibias, as the output of a current source. For example, Ibias=IDLL_bias if the circuit 200 of FIG. 2 is used as the current source. Ibias is received in an input path 311 of a current mirror 310. Ibias is a constant DC current in one implementation.

The output of the current mirror 310 is a first output path 313. This output path is also the input path of another current mirror 320. The output of the current mirror 320 is a second output path 321. The input path 311 includes an n-type transistor 312 coupled to ground. The first output path 313 includes, in series, a power supply node at Vcc (represented by a short horizontal line), a p-type transistor 322 and an adjustable transistor 323 representing a set of n-type transistors of different sizes, e.g., having different channel lengths and/or widths (areas). A transistor with a larger channel area will have a larger current for given biases at its terminals.

The current mirror 320 can be considered to be a first current mirror, where the input path 313 of the first current mirror is coupled to the output of the adaptive multi-stage filter by a second current mirror 310.

The second output path includes, in series, a power supply node, a p-type transistor 324 and a capacitor 326 (Cramp), coupled to ground. A node 325 of the second output path is at a voltage Vramp.

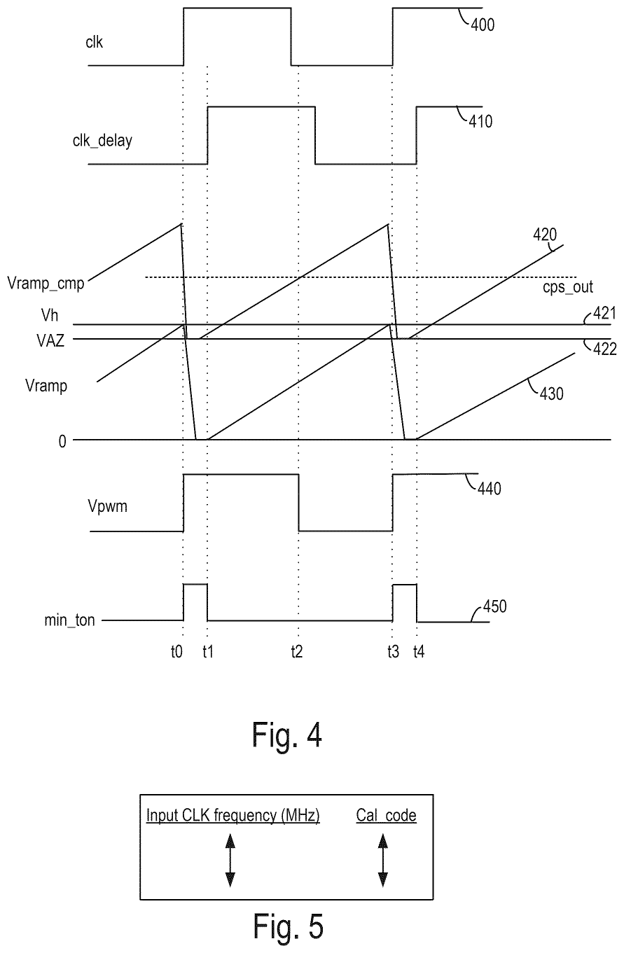

A digital calibration FSM 340 performs a fine trimming process of Vramp in the waveform generator. A calibration code, cal_code, on a path 341 is set by the digital calibration FSM 340 to select one of the transistors in the set of transistors 323 based on the clock frequency. In particular, the digital calibration FSM 340 receives a calibration result, cal_result, on a path 342 from an amplifier 343. The amplifier outputs cal_result based on a voltage Vh at its inverting input, Vramp at its non-inverting input, and a clock signal smp_clk. Vh is a voltage (see FIG. 4) to which Vramp from node 325 is compared. Vh is a desired peak level of Vramp. If Vramp is too high, the digital calibration FSM 340 will select a smaller transistor in set of transistors to reduce the current on the first output path 313. This in turn will reduce the current on the second output path 321 and therefore reduce Vramp, which is a voltage held on Cramp. The size of the transistor sets a current multiplier ratio of the current mirrors 310 and 320.

Vramp is a triangle waveform. See FIG. 4. A comparator 350 is used to provide a PWM signal, Vpwm, at an output node 351 based on Vramp. Vramp_cmp, provided at the inverting input of the comparator 350, corresponds to Vramp but has a higher voltage due to a voltage drop across a capacitor C1. The non-inverting input of the comparator receives a value which is based on the state of switches sw2, sw3 and sw4, each of which is controlled by a signal min_ton. When min-ton is high, sw2 and sw3 are closed (conductive) and sw4 is open (non-conductive). The open circle near sw4 denotes inversion of min_ton. With sw2 closed, Vramp is set to ground, e.g., 0 V. With sw3 closed and sw4 open, VAZ is provided to the non-inverting input of the comparator 350. VAZ is the minimum value of Vramp_cmp. With sw4 closed and sw3 open, cps_out is provided to the non-inverting input of the comparator 350. The comparator sets Vpwm to a high level when Vramp_cmp is less than cps_out, and to a low level when Vramp_cmp is greater than cps_out. Generally, Vramp is compared to a static DC signal at the non-inverting input. The duty cycle of the PWM signal is a function of the DC signal as well.

A feedback path 352 is provided from the output node 351 to the inverting input with a switch sw1 controlled by min_ton. The switch is closed when min_ton is high to provide the feedback. The node 351 may correspond to the node 122 in FIG. 1. The Vpwm depicted at the node 351 may be provided to the inverter 123 in FIG. 1.

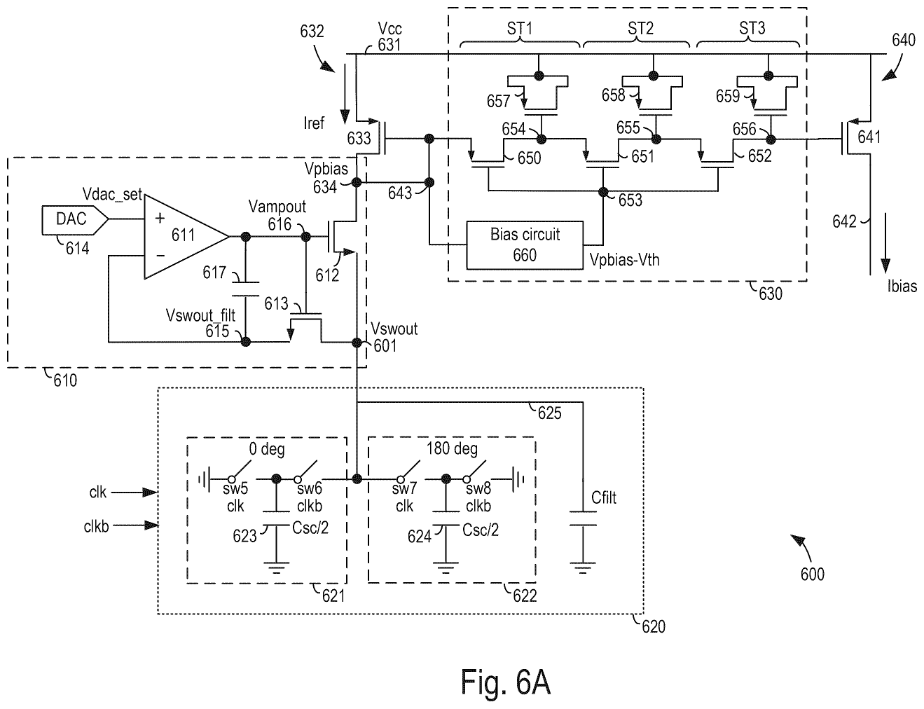

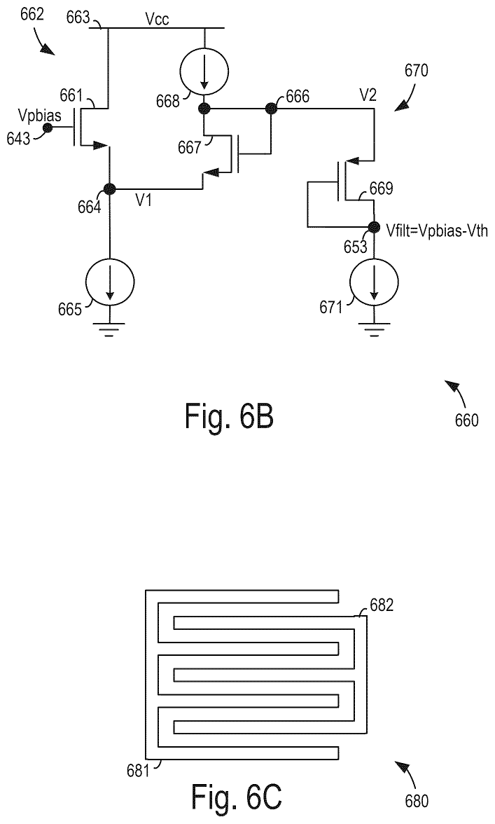

The waveform generator 120 thus generates a triangle waveform Vramp and then a PWM waveform Vpwm based on the received current from the current source. Compared to the circuit of FIG. 2, the current sources of FIGS. 6A, 7, 8 and 9 and the waveform generator of FIG. 3 provide current sources with a more linear relationship of Vpwm relative to clock frequency. By using corresponding capacitor designs, the current source and the waveform generator will have corresponding PVT variations. For example, the current source can use switched capacitors which are replicas of Cramp. PVT variations in Cramp which could affect Vpwm will be essentially cancelled out by corresponding variations in the switched capacitors and therefore the output current of the current source. Moreover, the Cramp and all the Csc capacitors can be on the same chip to achieve corresponding PVT variations.

In one implementation. Vramp is equal to tper/Cramp, wherein a current Iramp is equal to Ibias as expressed by Csc*Vdac_set*freq as in FIG. 6A. The value tper is the VR input clock period, through which Vramp is simplified as k*VDAC_set, which is easy to control. Ibias is linear with frequency.

FIG. 4 depicts example waveforms for use in the circuits of FIGS. 2 and 3, in accordance with various embodiments. The plots represent voltage in the vertical direction and time in the horizontal direction, with example time points t0-t4. Plots 400, 410, 440 and 450 are on separate voltage scales and plots 420 and 430 are on a common voltage scale. The plot 400 depicts a clock signal clk which is used to control switches such as in the current sources of FIGS. 6A, 7, 8 and 9. A complementary or antiphase signal clkb can also be provided. Plot 410 represents a delayed version of the clock, clk_delay.

Plot 420 depicts Vramp_cmp, the voltage input to the comparator 350 in FIG. 3. Vramp_cmp is a triangular waveform. Plot 421 depicts Vh, a voltage input to the amplifier 343 of FIG. 3. Plot 422 depicts VAZ, the voltage input to the switch sw3 of FIG. 3. Plot 430 depicts Vramp, the voltage held by Cramp in FIG. 3. Plot 440 depicts Vpwm, the output of the waveform generator 300. Plot 450 depicts min_ton, the voltage used to control the switches sw1-sw4 in FIG. 3. Min_ton is high from t0-t1 and t3-t4, when clk is high and clk_delay is low. Vramp_cmp has the same shape as Vramp but is elevated in voltage.

When Vramp_cmp falls below cps_out at t1, Vpwm goes high and remains high until t2, when Vramp_cmp increases above cps_out. Similarly, Vpwm goes high again at t3. The minimum level of Vramp_cmp is VAZ, and the minimum level of Vramp is 0 V, in this example.

FIG. 5 is an example table of variations in a calibration code, cal_code, versus input clock frequency for the circuit of FIG. 3, in accordance with various embodiments. A range of variations is represented by the vertical arrows. In FIG. 3, it was noted that the digital calibration FSM 340 outputs a calibration code to select one transistor from among a set of transistors 323 in a trim loop. Generally, the code shows a large systematic offset and random offset with the variance of several codes. This can result in cal_code saturation and therefore yield loss. Moreover, the variation is larger if the range of frequencies is expanded.

FIG. 6A depicts a continuous-time integrator-based circuit 600 including a continuous-time integrator 610, an adaptive multi-stage filter 630 and a switching circuit 620 having two-phases, in an example implementation of the current source 110 of FIG. 1, in accordance with various embodiments. By using switched capacitors, the circuit provides a resistor-less frequency-to-current converter. The circuit 600 can be used in place of the DLL-based circuit 200.

A power supply node 631 supplies a voltage Vcc to generate a reference current Iref in an input path 632 which includes, in series, a p-type transistor 633, a node 634 at Vbias, an n-type transistor 612, and a node 601 at Vsout, which in turn is coupled to the switching circuit. The switching circuit 620 modulates a voltage and current at the node 601 using switched-capacitor units 621 and 622 which are switched by different phases of a clock signals, e.g., 0 degrees and 180 degrees, respectively. That is, the switched-capacitor units correspond to two interleaved phases. The switched-capacitor units inject current to the node 601 which is filtered by the capacitor Cfilt. There will be still be some switching voltage noise, e.g., ˜100 mV, on the node 601 (Vswout) which is further filtered out by the integrator 610 such that the input noise of the amplifier 611 is only couple mV and the amplifier output voltage (Vampout) ripple is only a couple mV, for instance.

The amplifier 611 is part of a single-pole system since the Vswout node is a low impedance node where its pole is outside of the loop bandwidth. Accordingly, the control loop of the integrator 610 is stable from both a large signal and small signal perspective. However, the generated current in the input path 632 can be noisy. This is addressed by filtering at the multi-stage adaptive filter 630 to provide Ibias as a clean current. This filter 630 is adaptive to different clock frequencies, meaning it provides a high cut-off frequency at a high clock frequency and a low cut-off frequency at low clock frequency. Moreover, the resistance of the filter 630 is achieved with series-connected gate-controlled pMOS transistors 650-652 where the gate voltage is set to Vpbias−Vgs by a bias circuit 660. The resistance of the filter 630 is adaptive since the gate-to-source voltage, Vgs, generated at the transistors 650-652 is adaptive to the clock frequency. The filter 630 includes three resistance-capacitance (RC) stages ST1, ST2 and ST3 cascading together to achieve a sharper cut-off band. ST1 includes transistors 650 and 657. ST2 includes transistors 651 and 658. ST3 includes transistors 652 and 659.

This implementation is a resistor-less design to optimize area since all resistances are achieved from the gate-controlled transistors 650-652. This design improves scalability.

The current on the input path 632 is mirrored to an output path 640 using the adaptive multi-stage filter 630. The output path 640 includes a p-type transistor 641 having a control gate coupled to an output of the adaptive multi-stage filter 630 (node 656). A current Ibias is output on a path 642 for use by the waveform generator of FIG. 3, for example.

The switching circuit 600 can include multiple switched-capacitor units which are switched by different phases of a clock signal to reduce ripple in Vswout. The switched-capacitor unit 621 includes a switched-capacitor 623 with a capacitance Csc/2 coupled between switches sw5 and sw6 at one side and ground at the other side. Sw5 is grounded at one side and coupled to sw6 and the capacitor 623 at the other side. Sw6 is coupled to the node 601 at one side. Sw5 and sw6 are controlled by clock signals clk and clkb, respectively, where clkb is antiphase to clk.

Similarly, the switched-capacitor unit 622 includes a switched-capacitor 624 with a capacitance Csc/2 coupled between switches sw7 and sw8 at one side and ground at the other side. Sw8 is grounded at one side and coupled to sw7 and the capacitor 624 at the other side. Sw7 is coupled to the node 601 at one side. Sw7 and sw8 are controlled by clock signals clk and clkb, respectively. The node 601 is also coupled to ground via a path 625 and a filter capacitor, Cfilt.

When clk is high and clkb is low, the capacitor 623 is discharged to ground and the capacitor 624 is coupled to the node 601. When clk is low and clkb is high, the capacitor 624 is discharged to ground and the capacitor 623 is coupled to the node 601.

Vswout is low-pass filtered at the continuous-time integrator 610, which includes an amplifier 611 to drive control gate voltages of n-type transistors 612 and 613. The continuous-time integrator 610 filters switching noise from the switching circuit 620. The amplifier 611 receives a reference voltage Vdac_set from a DAC 614 at its non-inverting input and compares it to a value, Vswout_filt, on a feedback node 615 at its inverting input. Vswout_filt is a filtered version of Vswout. The voltage, Vampout, at the output 616 of the amplifier 611 is provided to a capacitor 617 and to control gate voltages of the n-type transistors 612 and 613.

The node 634 is coupled via a node 643 to the gate of the transistor 633, to the bias circuit 660 and to the stages ST1-ST3. The control gates of the transistors 650, 651 and 652 in ST1, ST2 and ST3, respectively, are coupled to the bias circuit 660. Node 654 between transistors 650 and 651, node 655 between transistors 651 and 652, and node 656 between transistor 652 and the gate of the transistor 641, are coupled to control gates of a series of p-type transistors 657, 658 and 659, respectively, in ST1, ST2 and ST3, respectively. The transistors 657-659 have their drain and source terminals coupled to the power supply node 631 and act as capacitors.

The transistors 650-652 act as variable resistors based on an output voltage Vpbias−Vth of the bias circuit at the node 653 which varies with, e.g., is adaptive relative to, Vpbias. See FIG. 6B. The resistance varies with Vpbias−Vth. The resistance is higher when Vpbias−Vth is higher. Vth is a threshold voltage of the transistor 661 in FIG. 6B.

The output of the adaptive multi-stage filter 630 is used to modulate the transistor 641 and thereby modulate the current on the Ibias on the path 642.

Note that the use of three series-connected p-type transistors 650-652 is an example only, as one or more can be used. Also, the use of the three capacitive transistors 657-659 is an example only, as one or more can be used.

The capacitors 623 and 624 in the current source and the capacitor Cramp in the waveform generator can be of the same type so that they have corresponding process, voltage and temperature (PVT) variations. See, e.g., FIG. 6C.

In an example implementation, the waveform generator 300 and the current source 600 together provide an apparatus comprising a switching circuit 620 comprising one or more switched capacitors 621 and 622; a continuous-time integrator 610 coupled to the switching circuit; an adaptive multi-stage filter 630 coupled to an output 634 of the continuous-time integrator; and a waveform generator 300, wherein the waveform generator comprises a current mirror 320 having an input path 313 and an output path 321, the input path is coupled to an output 642 of the adaptive multi-stage filter, the output path comprises a respective capacitor 326, and the one or more switched-capacitors and the respective capacitor are of the same type.

In another example implementation, the waveform generator 300 and the current source 600 together provide a system, comprising: a processor 1252; and a voltage regulator 100, 1200 coupled to the processor, wherein: the voltage regulator comprises a current source 600 and a waveform generator 300 coupled to the current source; the current source is to generate a current Ibias based on a voltage held on a switched-capacitor 623, 624; the waveform generator is to generate a waveform Vramp based on a voltage held on a respective capacitor 326, and a pulse-width modulation signal Vpwm based on the waveform; and the respective capacitor is a replica of the switched-capacitor.

FIG. 6B depicts an example implementation of the circuit 660 of FIG. 6A, in accordance with various embodiments. The circuit receives Vpbias at the node 643 and outputs Vfilt=Vpbias−Vth, where Vth is a threshold voltage of the n-type transistor 661. A first path 662 of the circuit includes, in series, a power supply node 663 at Vcc, the transistor 661, a node 664 at a voltage V1, and a current sink 665 coupled to ground. A voltage V2 is set at a node 666 based on a current through a diode-connected n-type transistor 667, where V2 is a function of V1 and a current source 668.

A second path 670 of the circuit includes, in series, a diode-connected p-type transistor 669, the node 653 and a current sink 671 coupled to ground. Vfilt is set at the node 653 based on a current through the transistor 669 which is a function of V2 and the current sink 671.

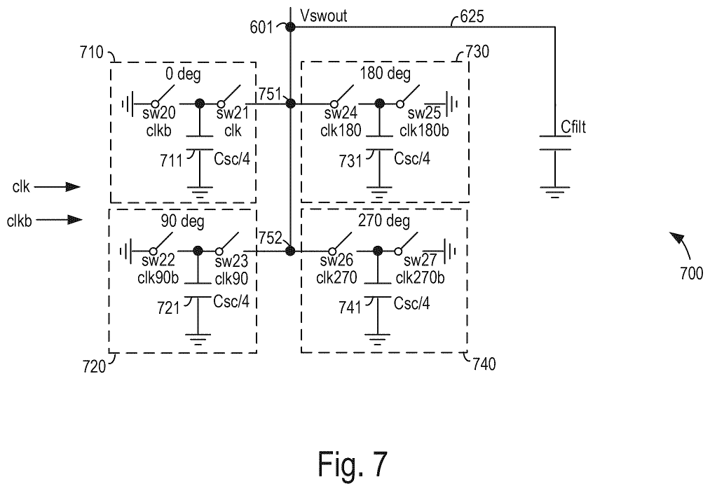

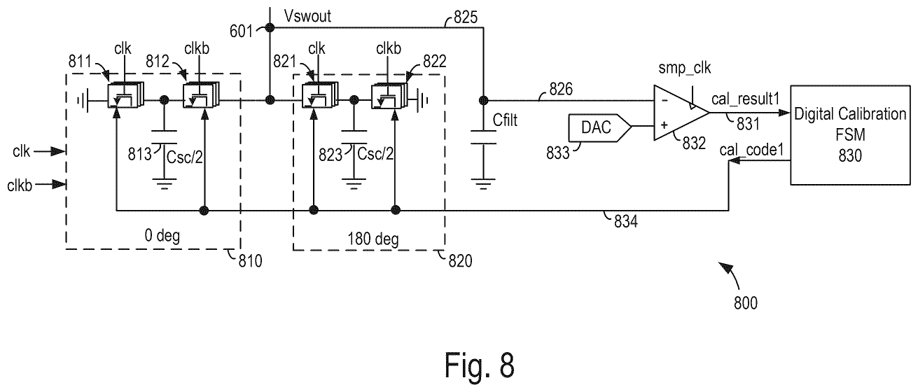

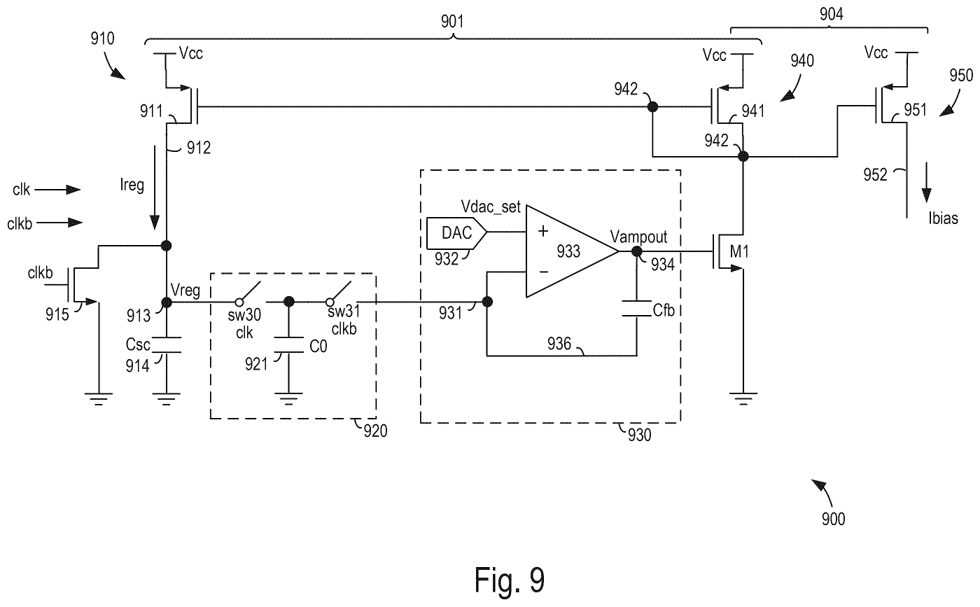

FIG. 6C depicts an example metal finger capacitor 680, such as for Cramp in FIG. 3, the capacitors 623 and 624 in FIG. 6A, the capacitors 711, 721, 731 and 741 in FIG. 7, the capacitors 813 and 823 in FIG. 8, and the capacitor 914 in FIG. 9, in accordance with various embodiments. As mentioned, the capacitors in the current source and the waveform generator can be of the same type so that they have corresponding process, voltage and temperature (PVT) variations. One example type of a capacitor is a metal finger capacitor which includes interdigitated portions 681 and 682 in one or more layers. One layer is shown in this example. The capacitors can be replicas of one another. A replica can include, e.g., being of the same size or having the same proportions, being of the same type and/or having the same metal composition. The capacitors can be multi-finger capacitors composed of one or more metal layers. The capacitors can have the same number of metal layers. The capacitors can be multi-finger capacitors or other capacitors having the same metal composition including one or more of aluminum, tantalum or titanium. The capacitors can be fabricated on the same chip. Other types of capacitors besides multi-finger capacitors can be used as well.

Generally, different types of on-chip capacitors include metal-insulator-metal (MIM), metal-oxide-metal (MOM), metal-oxide-semiconductor (MOS), trench and metal fringe. A MIM can be implemented with a simple structure with two parallel metal layers and an insulator, where the insulator is a high k-dielectric and the structures can be stacked. A MOM is similar to the MIM, but uses an oxide layer as the insulator. The MOS uses a MOS transistor as a capacitor. A thin oxide layer in the gate acts as the insulator. The MOS essentially acts as a varactor, where the capacitance depends on any applied DC voltage. In a trench capacitor, the bottom contact and the insulator are buried deep into the substrate. The top contact is connected to a circuit or power, and the bottom contact is grounded. A metal fringe capacitor has an interdigitated structure that relies on fringing fields to provide most of the capacitance.

The similarities of the capacitors helps reduce non-linear behavior and improve accuracy in the generation of Vramp.

FIG. 7 depicts an example four-phase switching circuit 700 as an alternative to the switching circuit 620 of FIG. 6A, in accordance with various embodiments. The switching circuit 700 is coupled to the node 601, path 625 and Cfilt as in FIG. 6A. The switching circuit includes four switched-capacitor units 710, 720, 730 and 740 which are switched by four different phases of the clock signal, e.g., 0, 90, 180 and 270 degrees, respectively. That is, the switched-capacitor units correspond to four interleaved phases. The switched-capacitor units 710 and 720 are configured similarly as the switched-capacitor unit 621, and the switched-capacitor units 730 and 740 are configured similarly as the switched-capacitor unit 622. The node 601 is coupled to the switched-capacitor units 710 and 730 via a node 751, and to the switched-capacitor units 720 and 740 via a node 752.

The switched-capacitor unit 710 includes a switched-capacitor 711 with a capacitance Csc/4 coupled between switches sw20 and sw21 at one side and ground at the other side. Sw20 is grounded at one side and coupled to sw21 and the capacitor 711 at the other side. Sw21 is coupled to the node 751 at one side. Sw20 and sw21 are controlled by clock signals clkb and clk, respectively.

The switched-capacitor unit 720 includes a switched-capacitor 721 with a capacitance Csc/4 coupled between switches sw22 and sw23 at one side and ground at the other side. Sw22 is grounded at one side and coupled to sw23 and the capacitor 721 at the other side. Sw23 is coupled to the node 752 at one side. Sw22 and sw23 are controlled by clock signals clk90b and clk90, respectively. Clk90 is 90 degrees out of phase with clk and clk90b is antiphase with clk90.

The switched-capacitor unit 730 includes a switched-capacitor 731 with a capacitance Csc/4 coupled between switches sw24 and sw25 at one side and ground at the other side. Sw25 is grounded at one side and coupled to sw24 and the capacitor 731 at the other side. Sw24 is coupled to the node 751 at one side. Sw24 and sw25 are controlled by clock signals clk180 and clk180b, respectively. Clk180 is 180 degrees out of phase with clk and clk180b is antiphase with clk180.

The switched-capacitor unit 740 includes a switched-capacitor 741 with a capacitance Csc/4 coupled between switches sw26 and sw27 at one side and ground at the other side. Sw27 is grounded at one side and coupled to sw26 and the capacitor 741 at the other side. Sw26 is coupled to the node 752 at one side. Sw26 and sw27 are controlled by clock signals clk270 and clk270b, respectively. Clk270 is 270 degrees out of phase with clk and clk270b is antiphase with clk270.

The capacitors 711, 721, 731 and 741 in the current source and the capacitor Cramp in the waveform generator can be of the same type so that they have corresponding PVT variations.

FIG. 8 depicts an example switching circuit 800 with switch size modulation as an alternative to the switching circuit 620 of FIG. 6A, in accordance with various embodiments. This example includes two switched-capacitor units 810 and 820 similar to FIG. 6A, but four switched-capacitor units similar to FIG. 7 could be used or some other number of switched-capacitor units. Each switched-capacitor unit includes a set of transistors which act as switches that are controlled by a clock signal clk or clkb. In each set, one of the transistors is selected based on a calibration code, cal_code1, output from a digital calibration FSM 830 on a path 834, similar to the FSM 340 of FIG. 3. In each set, the transistors are of different sizes, e.g., having different channel lengths and/or widths (areas). A transistor with a larger channel area will have a larger current for a given set of biases at its source, drain and gate terminals. A larger current will result in a larger Vswout. The FSM can find an optimum switch size/resistance that guarantees that, for each charge injection from the capacitors to the node 601, Vswout will settle to the desired value set by the DAC 833. The FSM implements a digital control loop to choose the optimum sized switch as the clock frequency varies.

The digital calibration FSM 830 is responsive to a voltage, cal-result1, at the output 831 of an amplifier 832. The amplifier receives Vswout via paths 825 and 826 at an inverting input and a reference voltage from a DAC 833 at a non-inverting input. Note that cal_result1 and cal_code1 are different than cal_result and cal_code, respectively, in FIG. 3 since the FSMs 340 and 830 are for different purposes.

The switched-capacitor unit 810 includes a switched-capacitor 813 with a capacitance Csc/2 coupled between sets of switches 811 and 812 at one side and ground at the other side. The set of switches 811 is grounded at one side and coupled to the set of switches 812 and the capacitor 813 at the other side. The set of switches 812 is coupled to the node 601 at one side. The sets of switches 811 and 812 are controlled by clock signals clk and clkb, respectively.

The switched-capacitor unit 820 includes a switched-capacitor 823 with a capacitance Csc/2 coupled between sets of switches 821 and 822 at one side and ground at the other side. The set of switches 822 is grounded at one side and coupled to the set of switches 821 and the capacitor 823 at the other side. The set of switches 821 is coupled to the node 601 at one side. The sets of switches 821 and 822 are controlled by clock signals clk and clkb, respectively.

The capacitors 813 and 823 in the current source and the capacitor Cramp in the waveform generator can be of the same type so that they have corresponding PVT variations.

FIG. 9 depicts a discrete-time integrator-based circuit 900 in an example implementation of the current source 110 of FIG. 1, in accordance with various embodiments. The circuit 900 provides a discrete-time integrator-based frequency-to-current converter.

The circuit 900 includes a first current mirror 901 having an input path 910 and an output path 940 (a first output path), and a second current mirror 904 in which the path 940 is the input path and a second output path 950 is the output path. The input path 910 includes, in series, a power supply node at Vcc, a p-type transistor 911, a path 912, a node 913 having a voltage Vreg, and a switched capacitor 914 (Csc) coupled to ground.

A current, Ireg, which is a regulated DC current, is generated in the input path 910. Ireg charges Csc at the end of each sampling cycle. An n-type transistor 915 can couple the path 912 to ground when a voltage at its control gate clkb is low (e.g., 0 V).

A sample-and-hold circuit 920 is coupled to the node 913. The sample-and-hold circuit includes a switched-capacitor 921 with a capacitance C0 coupled between switches sw30 and sw31 at one side and ground at the other side. Sw30 is coupled to the node 913 on one side and to the capacitor 921 and sw31 on the other side. Sw31 is coupled to a node 931 at one side. Sw30 and sw31 are controlled by clock signals clk and clkb, respectively. The sample-and-hold circuit samples Vreg and holds it on the capacitor 921.

A switched capacitor is a capacitor which is constantly charging and discharging due to switches. Csc and C0 are switched capacitors in FIG. 9. Ireg (=Ibias) is determined by Csc and not by C0 since C0 is just used for sampling. Matching the Csc capacitors to Cramp is what helps maintain the linearity of Ibias. Vreg is sampled by the sample-and-hold circuit 920 while the discrete-time integrator 930 regulates the sampled Vreg to the targeted reference voltage. To stabilize this loop, the voltage gain in a cycle of sample-and-hold should be much smaller than 1, which requires gm1*C0/Cfb to be small (gm1 denotes transconductance). This equation can be expanded to: gm1*T*(C0/Cfb)/(Csc+C0)<<1, where T is the time when the clock is logic high at each clock period. Once startup is completed, Vampout and Ireg are essentially ripple-free. The switching noise is filtered by the sample-and-hold circuit together with the discrete-time integrator 930.

The node 931 is part of a discrete-time integrator 930 which includes a DAC 932, an amplifier 933, an output node 934, and a feedback capacitor Cfb in a feedback path 936. The discrete-time integrator 930 filters switching noise from the sample-and-hold circuit 920. The DAC 932 provides a reference voltage, Vdac_set, to the non-inverting input of the amplifier 933 while the feedback path 936 is coupled to the inverting input of the amplifier 933. In response to the inputs, the amplifier outputs a voltage, Vampout, at the output node 934, to control the conductivity of an n-type transistor M1 in the first output path 940. This controls the amount of the current Iref mirrored from the input path 910 to the first output path 940.

The first output path 940 includes, in series, a power supply node at Vcc, a p-type transistor 941, a node 942, and the n-type transistor M1. The transistor 941 is diode-connected with its control gate coupled to a control gate of the transistor 911 via a node 942 and its drain coupled to the node 942.

The second output path 950 includes, in series, a power supply node at Vcc, a p-type transistor 951 and an output path 952 which provides a current Ibias for use by the waveform generator. The second current mirror 904 mirrors the current on the first output path 940 to the second output path 950.

The capacitor Csc in the current source 900 and the capacitor Cramp in the waveform generator 300 can be of the same type so that they have corresponding PVT variations.

In an example implementation, the waveform generator 300 and the current source 900 together provide an apparatus comprising an input path 910, a first output path 940 and a second output path 950, wherein the input path is configured to receive a regulation current Ireg, and the input path comprises a respective capacitor 914 to hold a voltage corresponding to the regulation current; a sample-and-hold circuit 920 coupled to the input path; and a discrete-time integrator 930 coupled to the sample-and-hold circuit; wherein the first output path is configured to mirror the regulation current of the input path based on an output of the discrete-time integrator, and the second output path is configured to mirror a current of the first output path to provide a bias current; and a waveform generator 300, wherein the waveform generator is coupled to the second output path and comprises a respective capacitor 326 configured to hold a voltage corresponding to the bias current and to generate a pulse-width modulation signal Vpwm based on the voltage.

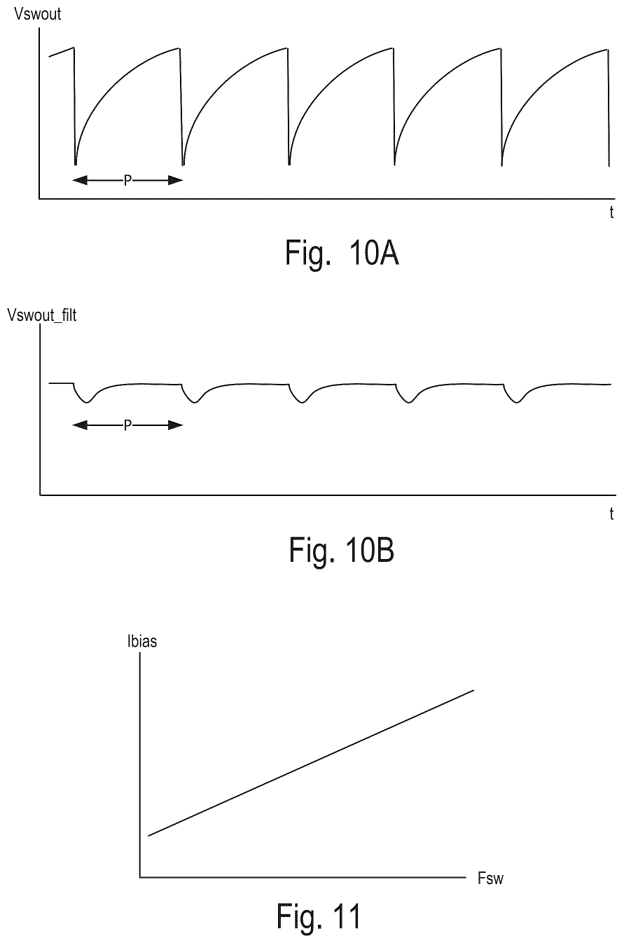

FIG. 10A depicts an example plot of Vswout versus time consistent with the circuit of FIG. 6A, in accordance with various embodiments. The discrete-time integrator design of FIG. 9 provides similar results.

The arrow represents a period P of the clock (clk). Vswout increases from a minimum level to a maximum level in each clock period. Referring to the switched-capacitor units 621 and 622 in FIG. 6A, for example, when clk is high, sw5 is closed (conductive) so that the capacitor 623 is discharged to ground and sw7 is closed so that the node 601 at Vswout is charged by the capacitor 624, resulting in the gradual increase in Vswout. Similarly, when clkb is high, sw8 is closed (conductive) so that the capacitor 624 is discharged to ground and sw6 is closed so that the node 601 at Vswout is charged by the capacitor 623.

FIG. 10B depicts an example plot of Vswout_filt versus time consistent with the circuit of FIG. 6A and the plot of FIG. 10A, in accordance with various embodiments. Vswout_filt is regulated in a control loop at the continuous-time integrator 610. The plot shows that Vswout_filt experiences an initial droop at the start of the clock period then recovers quickly to a steady state level.

FIG. 11 depicts an example plot of Ibias versus switching frequency (Fsw) consistent with the circuits of FIGS. 6A and 9, in accordance with various embodiments. The plot demonstrates that Ibias advantageously increases linearly as the switching frequency increases.

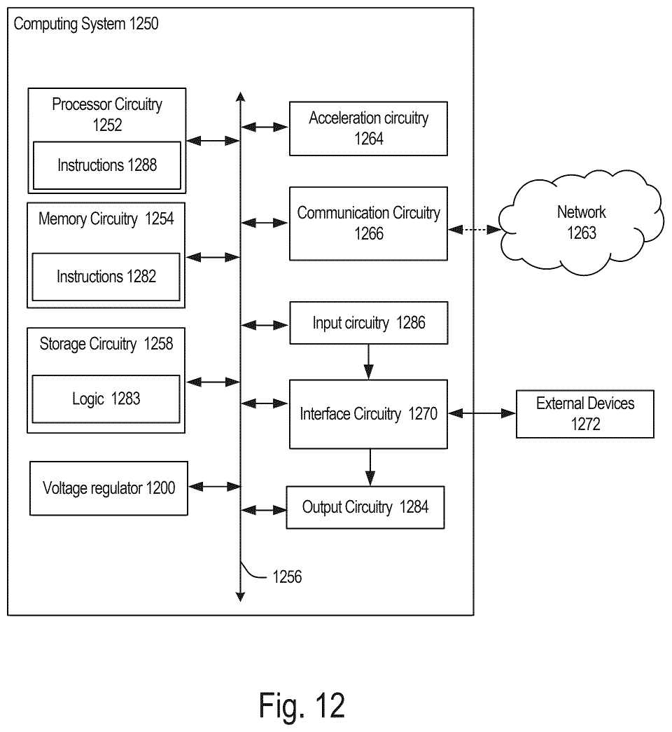

FIG. 12 illustrates an example of components that may be present in a computing system 1250 for implementing the techniques (e.g., operations, processes, methods, and methodologies) described herein.

The computing system 1250 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 1250, or as components otherwise incorporated within a chassis of a larger system. The waveform generator 300 of FIG. 3 and the circuit 600 FIG. 6A or 900 of FIG. 9 can be provided as part of the voltage regulator 1200. The other circuitry in the computing system 1250 can represent one or more circuits/loads which are powered by the VR. In one approach, all or part of the computing system 1250 is provided in a SoP, System-in-Package (SiP) or a System-on-Chip (SoC).

The voltage regulator can provide a voltage Vout to one or more of the components of the computing system 1250. The memory circuitry 1254 may store instructions and the processor circuitry 1252 may execute the instructions to perform the functions described herein.

The system 1250 includes processor circuitry in the form of one or more processors 1252. The processor circuitry 1252 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 1252 may include one or more hardware accelerators (e.g., same or similar to acceleration circuitry 1264), which may be microprocessors, programmable processing devices (e.g., FPGA, ASIC, etc.), or the like. The one or more accelerators may include, for example, computer vision and/or deep learning accelerators. In some implementations, the processor circuitry 1252 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 1252 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 1252 may be coupled with or may include memory/storage and may be configured to execute instructions stored in the memory/storage to enable various applications or operating systems to run on the platform 1250. The processors (or cores) 1052 is configured to operate application software to provide a specific service to a user of the platform 1250. In some embodiments, the processor(s) 1252 may be a special-purpose processor(s)/controller(s) configured (or configurable) to operate according to the various embodiments herein.

As examples, the processor(s) 1252 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 1252 may be a part of a system on a chip (SoC), System-in-Package (SiP), a multi-chip package (MCP), and/or the like, in which the processor(s) 1252 and other components are formed into a single integrated circuit, or a single package, such as the Edison™ or Galileo™ SoC boards from Intel® Corporation. Other examples of the processor(s) 1252 are mentioned elsewhere in the present disclosure.

The system 1250 may include or be coupled to acceleration circuitry 1264, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 1264 may comprise logic blocks or logic fabric and other interconnected resources that may be programmed (configured) to perform various functions, such as the procedures, methods, functions, etc. of the various embodiments discussed herein. In such implementations, the acceleration circuitry 1264 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 1252 and/or acceleration circuitry 1264 may include hardware elements specifically tailored for machine learning and/or artificial intelligence (AI) functionality. In these implementations, the processor circuitry 1252 and/or acceleration circuitry 1264 may be, or may include, an AI engine chip that can run many different kinds of AI instruction sets once loaded with the appropriate weightings and training code. Additionally or alternatively, the processor circuitry 1252 and/or acceleration circuitry 1264 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPS™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 1252 and/or acceleration circuitry 1264 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin provided by Huawei®, and/or the like. In some hardware-based implementations, individual subsystems of system 1250 may be operated by the respective AI accelerating co-processor(s), AI GPUs, TPUs, or hardware accelerators (e.g., FPGAS, ASICs, DSPs, SoCs, etc.), etc., that are configured with appropriate logic blocks, bit stream(s), etc. to perform their respective functions.

The system 1250 also includes system memory 1254. Any number of memory devices may be used to provide for a given amount of system memory. As examples, the memory 1254 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 1254 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 1254 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 1258 provides persistent storage of information such as data, applications, operating systems and so forth. In an example, the storage 1258 may be implemented via a solid-state disk drive (SSDD) and/or high-speed electrically erasable memory (commonly referred to as “flash memory”). Other devices that may be used for the storage 1258 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 1254 and/or storage circuitry 1258 may also incorporate three-dimensional (3D) cross-point (XPOINT) memories from Intel® and Micron®.

The memory circuitry 1254 and/or storage circuitry 1258 is/are configured to store computational logic 1283 in the form of software, firmware, microcode, or hardware-level instructions to implement the techniques described herein. The computational logic 1283 may be employed to store working copies and/or permanent copies of programming instructions, or data to create the programming instructions, for the operation of various components of system 1250 (e.g., drivers, libraries, application programming interfaces (APIs), etc.), an operating system of system 1250, one or more applications, and/or for carrying out the embodiments discussed herein. The computational logic 1283 may be stored or loaded into memory circuitry 1254 as instructions 1282, or data to create the instructions 1282, which are then accessed for execution by the processor circuitry 1252 to carry out the functions described herein. The processor circuitry 1252 and/or the acceleration circuitry 1264 accesses the memory circuitry 1254 and/or the storage circuitry 1258 over the interconnect (IX) 1256. The instructions 1282 direct the processor circuitry 1252 to perform a specific sequence or flow of actions, for example, as described with respect to flowchart(s) and block diagram(s) of operations and functionality depicted previously. The various elements may be implemented by assembler instructions supported by processor circuitry 1252 or high-level languages that may be compiled into instructions 1288, or data to create the instructions 1288, to be executed by the processor circuitry 1252. The permanent copy of the programming instructions may be placed into persistent storage devices of storage circuitry 1258 in the factory or in the field through, for example, a distribution medium (not shown), through a communication interface (e.g., from a distribution server (not shown)), over-the-air (OTA), or any combination thereof.

The IX 1256 couples the processor 1252 to communication circuitry 1266 for communications with other devices, such as a remote server (not shown) and the like. The communication circuitry 1266 is a hardware element, or collection of hardware elements, used to communicate over one or more networks 1263 and/or with other devices. In one example, communication circuitry 1266 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 1266 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 1256 also couples the processor 1252 to interface circuitry 1270 that is used to connect system 1250 with one or more external devices 1272. The external devices 1272 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 1250, which are referred to as input circuitry 1286 and output circuitry 1284. The input circuitry 1286 and output circuitry 1284 include one or more user interfaces designed to enable user interaction with the platform 1250 and/or peripheral component interfaces designed to enable peripheral component interaction with the platform 1250. Input circuitry 1286 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 1284 may be included to show information or otherwise convey information, such as sensor readings, actuator position(s), or other like information. Data and/or graphics may be displayed on one or more user interface components of the output circuitry 1284. Output circuitry 1284 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 1250. The output circuitry 1284 may also include speakers and/or other audio emitting devices, printer(s), and/or the like. Additionally or alternatively, sensor(s) may be used as the input circuitry 1284 (e.g., an image capture device, motion capture device, or the like) and one or more actuators may be used as the output device circuitry 1284 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 1250 may communicate over the IX 1256. The IX 1256 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 1256 may be a proprietary bus, for example, used in a SoC based system.

The number, capability, and/or capacity of the elements of system 1250 may vary, depending on whether computing system 1250 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 1250 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: a switching circuit comprising one or more switched capacitors; a continuous-time integrator coupled to the switching circuit; an adaptive multi-stage filter coupled to an output of the continuous-time integrator; and a waveform generator, wherein the waveform generator comprises a current mirror having an input path and an output path, the input path is coupled to an output of the adaptive multi-stage filter, the output path comprises a respective capacitor, and the one or more switched capacitors and the respective capacitor are of the same type.

Example 2 includes the apparatus of Example 1, wherein the one or more switched capacitors and the respective capacitor are multi-finger capacitors.

Example 3 includes the apparatus of Example 1 or 2, wherein the one or more switched capacitors and the respective capacitor are multi-finger capacitors having the same metal composition.

Example 4 includes the apparatus of any one of Examples 1-3, wherein the one or more switched capacitors and the respective capacitor are on the same chip and have corresponding process, voltage and temperature variations.

Example 5 includes the apparatus of any one of Examples 1-4, wherein the current mirror is a first current mirror, and the input path of the first current mirror is coupled to the output of the adaptive multi-stage filter by a second current mirror.

Example 6 includes the apparatus of any one of Examples 1-5, wherein the one or more switched capacitors comprise a plurality of switched capacitors which are switched by different phases of a clock signal.

Example 7 includes the apparatus of any one of Examples 1-6, wherein the adaptive multi-stage filter comprise one or more resistance-capacitance stages.

Example 8 includes the apparatus of any one of Examples 1-7, wherein: the switching circuit comprises a set of transistors, and transistors of the set of transistors have different sizes; and the switching circuit comprises a finite state machine to set a calibration code to select one transistor among the set of transistors.

Example 9 includes the apparatus of any one of Examples 1-8, wherein the respective capacitor is configured to hold a voltage based on a current of the output of the adaptive multi-stage filter.

Example 10 includes the apparatus of Example 9, wherein: the voltage comprises a triangular waveform; the waveform generator further comprises a comparator coupled to the respective capacitor; and the comparator is configured to output a pulse-wave modulation signal based on the triangular waveform.

Example 11 includes the apparatus of any one of Examples 1-10, wherein: the input path of the current mirror comprises a set of transistors, and transistors of the set of transistors have different sizes; and the waveform generator comprises a finite state machine to set a calibration code to select one transistor among the set of transistors.

Example 12 includes the apparatus of any one of Examples 1-11, further comprising a switched capacitor voltage regulator which includes the switching circuit, the continuous-time integrator, the adaptive multi-stage filter, and the waveform generator, wherein the switched capacitor voltage regulator is provided in at least one of an integrated circuit, a System-on-Chip, a System-in-Package, or a computing device.

Example 13 includes an apparatus, comprising: an input path, a first output path and a second output path, wherein the input path is configured to receive a regulation current, and the input path comprises a respective capacitor to hold a voltage corresponding to the regulation current; a sample-and-hold circuit coupled to the input path; and a discrete-time integrator coupled to the sample-and-hold circuit; wherein the first output path is configured to mirror the regulation current of the input path based on an output of the discrete-time integrator, and the second output path is configured to mirror a current of the first output path to provide a bias current; and a waveform generator, wherein the waveform generator is coupled to the second output path and comprises a respective capacitor configured to hold a voltage corresponding to the bias current and to generate a pulse-width modulation signal based on the voltage.

Example 14 includes the apparatus of Example 13, further comprising a transistor in the first output path, wherein a control gate of the transistor is coupled to the output of the discrete-time integrator.

Example 15 includes the apparatus of Example 13 or 14, wherein: the discrete-time integrator comprises an amplifier having an inverting input and a non-inverting input; the output of the discrete-time integrator is an output of the amplifier; the sample-and-hold circuit comprises a first switch coupled to the input path, a second switch coupled to the inverting input, and a capacitor coupled between first and second switches; the first switch is controlled by a first clock signal; and the second switch is controlled by a second clock signal which is antiphase relative to the first clock signal.

Example 16 includes the apparatus of Example 15, further comprising a transistor coupled to the input path and to a ground, wherein the transistor is to receive the second clock signal at its control gate.

Example 17 includes the apparatus of any one of Examples 13-16, wherein the respective capacitors of the input path and the waveform generator have corresponding process, voltage and temperature variations.

Example 18 includes a system, comprising: a processor; and a voltage regulator coupled to the processor, wherein: the voltage regulator comprises a current source and a waveform generator coupled to the current source; the current source is to generate a current based on a voltage held on a switched capacitor; the waveform generator is to generate a waveform based on a voltage held on a respective capacitor, and a pulse-width modulation signal based on the waveform; and the respective capacitor is a replica of the switched capacitor.

Example 19 includes the system of Example 18, wherein the switched capacitor and the respective capacitor are on the same chip and have corresponding process, voltage and temperature variations.

Example 20 includes the system of Example 18 or 19, wherein the respective capacitor is a scaled version of the switched capacitor.

Example 21 includes a method, comprising: receiving a clock signal at a switching circuit comprising one or more switched capacitors; based on the clock signal, controlling switches of the switching circuit to provide a time-varying voltage and current; low-pass filtering the voltage and the current at a continuous-time integrator; filtering an output of the continuous-time integrator at an adaptive multi-stage filter; and providing an output current of the adaptive multi-stage filter as an input current to a waveform generator, wherein the waveform generator comprises a current mirror having an input path and an output path, the input path is coupled to an output of the adaptive multi-stage filter, the output path comprises a respective capacitor, and the one or more switched capacitors and the respective capacitor are of the same type.

Example 22 includes the method of Example 21, wherein the waveform generator provides a pulse-width modulation signal based on the input current.

Example 23 includes an apparatus comprising means to perform the method of Example 21 or 22.

Example 24 includes a machine-readable storage including machine-readable instructions, when executed, cause a computer to implement the method of Example 21 or 22.

Example 25 includes a computer program comprising instructions which, when executed by a computer, cause the computer to carry out the method of Example 21 or 22.

Example 26 includes a method, comprising: receiving a regulation current at an input path, wherein the input path comprises a respective capacitor to hold a voltage corresponding to the regulation current, a sample-and-hold circuit is coupled to the input path, and a discrete-time integrator is coupled to the sample-and-hold circuit; mirroring the regulation current of the input path on a first output path based on an output of the discrete-time integrator; mirroring a current of the first output path at a second output path to provide a bias current; and at a waveform generator coupled to the second output: holding a voltage corresponding to the bias current at a respective capacitor of a waveform generator and generating a pulse-width modulation signal based on the voltage.

Example 27 includes the method of Example 26, further comprising receiving the second clock signal at a control gate of a transistor coupled to the input path.

Example 28 includes an apparatus comprising means to perform a method of Example 26 or 27.

Example 29 includes a machine-readable storage including machine-readable instructions, when executed, cause a computer to implement the method of Example 26 or 27.

Example 30 includes a computer program comprising instructions which, when executed by a computer, cause the computer to carry out the method of Example 26 or 27.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a switching circuit comprising one or more switched capacitors;
a continuous-time integrator coupled to the switching circuit;
an adaptive multi-stage filter coupled to an output of the continuous-time integrator; and
a waveform generator, wherein the waveform generator comprises a current mirror having an input path and an output path, the input path is coupled to an output of the adaptive multi-stage filter, the output path comprises a respective capacitor, and the one or more switched capacitors and the respective capacitor are of the same type.

2. The apparatus of claim 1, wherein the one or more switched capacitors and the respective capacitor are multi-finger capacitors.

3. The apparatus of claim 1, wherein the one or more switched capacitors and the respective capacitor are multi-finger capacitors having the same metal composition.

4. The apparatus of claim 1, wherein the one or more switched capacitors and the respective capacitor are on the same chip and have corresponding process, voltage and temperature variations.

5. The apparatus of claim 1, wherein the current mirror is a first current mirror, and the input path of the first current mirror is coupled to the output of the adaptive multi-stage filter by a second current mirror.

6. The apparatus of claim 1, wherein the one or more switched capacitors comprise a plurality of switched capacitors which are switched by different phases of a clock signal.

7. The apparatus of claim 1, wherein the adaptive multi-stage filter comprise one or more resistance-capacitance stages.

8. The apparatus of claim 1, wherein:
the switching circuit comprises a set of transistors, and transistors of the set of transistors have different sizes; and
the switching circuit comprises a finite state machine to set a calibration code to select one transistor among the set of transistors.

9. The apparatus of claim 1, wherein the respective capacitor is configured to hold a voltage based on a current of the output of the adaptive multi-stage filter.

10. The apparatus of claim 9, wherein:
the voltage comprises a triangular waveform;
the waveform generator further comprises a comparator coupled to the respective capacitor; and
the comparator is configured to output a pulse-wave modulation signal based on the triangular waveform.

11. The apparatus of claim 1, wherein:
the input path of the current mirror comprises a set of transistors, and transistors of the set of transistors have different sizes; and
the waveform generator comprises a finite state machine to set a calibration code to select one transistor among the set of transistors.

12. The apparatus of claim 1, further comprising a switched-capacitor voltage regulator which includes the switching circuit, the continuous-time integrator, the adaptive multi-stage filter, and the waveform generator, wherein the switched-capacitor voltage regulator is provided in at least one of an integrated circuit, a System-on-Chip, a System-in-Package, or a computing device.

13. An apparatus, comprising:
an input path, a first output path and a second output path, wherein the input path is configured to receive a regulation current, and the input path comprises a respective capacitor to hold a voltage corresponding to the regulation current;
a sample-and-hold circuit coupled to the input path; and
a discrete-time integrator coupled to the sample-and-hold circuit;
wherein the first output path is configured to mirror the regulation current of the input path based on an output of the discrete-time integrator, and the second output path is configured to mirror a current of the first output path to provide a bias current; and
a waveform generator, wherein the waveform generator is coupled to the second output path and comprises a respective capacitor configured to hold a voltage corresponding to the bias current and to generate a pulse-width modulation signal based on the voltage.

14. The apparatus of claim 13, further comprising a transistor in the first output path, wherein a control gate of the transistor is coupled to the output of the discrete-time integrator.

15. The apparatus of claim 13, wherein:
the discrete-time integrator comprises an amplifier having an inverting input and a non-inverting input;
the output of the discrete-time integrator is an output of the amplifier;
the sample-and-hold circuit comprises a first switch coupled to the input path, a second switch coupled to the inverting input, and a capacitor coupled between first and second switches;
the first switch is controlled by a first clock signal; and
the second switch is controlled by a second clock signal which is antiphase relative to the first clock signal.

16. The apparatus of claim 15, further comprising a transistor coupled to the input path and to a ground, wherein the transistor is to receive the second clock signal at its control gate.

17. The apparatus of claim 13, wherein the respective capacitors of the input path and the waveform generator have corresponding process, voltage and temperature variations.

18. A system, comprising:
a processor; and
a voltage regulator coupled to the processor, wherein:
the voltage regulator comprises a current source and a waveform generator coupled to the current source;
the current source is to generate a current based on a voltage held on a switched-capacitor;
the waveform generator is to generate a waveform based on a voltage held on a respective capacitor, and a pulse-width modulation signal based on the waveform; and
the respective capacitor is a replica of the switched-capacitor.

19. The system of claim 18, wherein the switched-capacitor and the respective capacitor are on the same chip and have corresponding process, voltage and temperature variations.

20. The system of claim 18, wherein the respective capacitor is a scaled version of the switched-capacitor.
